(19) United States
(12) Patent Application Publication
(10) Pub. No.: US 2021/0335981 A1
(43) Pub. Date: Oct. 28, 2021

(54) DISPLAY PANEL, MANUFACTURING METHOD THEREOF AND RELATED DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Tao Zhang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/623,526

(22) PCT Filed: Oct. 18, 2019
(86) PCT No.: PCT/CN2019/111792

§ 371 Date: Dec. 17, 2019

(30) Foreign Application Priority Data
Jun. 24, 2019 (CN) 201910546800.6

(51) Int. Cl. H01L 27/32; H01L 51/56

(52) U.S. Cl. CPC H01L 27/3276; H01L 51/5012; H01L 51/56

(57) ABSTRACT

A display panel, a manufacturing method, and a display device are provided. The display panel includes: a substrate; a signal line layer having an edge pasted on an edge of a display area; an insulating layer having an edge pasted on an edge of the signal line layer; a light emitting layer comprising lighting devices arranged with spaces; and a via, pass through the organic lighting devices and the insulating layer from a cathode layer of the organic lighting devices to a surface of the signal line layer. The present disclosure positions the signal lines under the middle portion of the display area and utilizes a via to connect the cathode layer of the display area to the signal lines. Therefore, there is no need to put the signal lines in the side frame area such that the narrow side frame design is accomplished.

### FIELD OF THE INVENTION

The present invention relates to display field, and more particularly to a display panel, manufacturing method thereof and related display device.

### BACKGROUND

As the progress of the display technology and various products in the market, people have more and more demands on the display panel, especially the display of a cell phone. The aesthetics of the cell phone is very essential. A cell phone with a narrow side frame or with no side frame becomes the development trend.

OLED (organic light emitting diode) display comprises a display area and a side frame area where the side frame area is on one side of the display area. There are signal lines in the side frame area. The cathode metal layer of the OLED devices is in the display area and connected to the signal lines to form a bridging area such that the signal transmission is performed. However, the bridging area occupies a large area of the side frame. This makes it difficult to reduce the size of the side frame and affects the appearance of the display panel.

From the above, the issue of wide side frames of the display panel needs to be addressed.

### SUMMARY

One objective of an embodiment of the present invention is to provide a display panel and its manufacturing method to solve the above-mentioned problem of wide side frames.

According to an embodiment of the present invention, a display panel is provided. The display panel comprises: a substrate, comprising a display area; a signal line layer, positioned above the substrate, the signal line layer having an edge pasted on an edge of the display area; an insulating layer, covering the signal line layer, the insulating layer having an edge pasted on an edge of the signal line layer; a light emitting layer, positioned above the insulating layer, the light emitting layer comprising a plurality of organic lighting devices arranged with spaces; and a via, pass through the organic lighting devices and the insulating layer from a cathode layer of the organic lighting devices to a surface of the signal line layer.

Optionally, a shape of a cross section of the via comprises a rectangular, a half circle, or a trapezoid and a maximum width of the via is less than or equal to 150 microns.

Optionally, each of the organic lighting devices comprises stacked a hole inject layer, a hole transport layer, an electroluminescent layer, an electron transport layer, and an electron inject layer; wherein the cathode layer is positioned above the electron injection layer.

Optionally, the insulating layer is manufactured with inorganic insulating material comprising one or a combination of silicon oxide, silicon nitride, and silicon oxynitride.

Optionally, the via is filled by a conductive material and the organic lighting devices are electrically connected to the signal line layer through the conductive material.

Optionally, the conductive material comprises one or a combination of silver, copper, or low temperature polysilicon.

Optionally, the display panel further comprises a packaging film layer covering the light emitting layer, and an edge of the packaging film layer is pasted on the edge of the display area.

According to an embodiment of the present invention, a manufacturing method for a display panel is provided. The manufacturing method comprises: providing a substrate comprising a display area; forming a signal line layer above the substrate, wherein an edge of the signal line layer is pasted on an edge of the display area; forming an insulating layer above the signal line layer, wherein the insulating layer extends to a boundary of the display area and a side frame area; forming a light emitting layer above the insulating layer, the light emitting layer comprising a plurality of organic lighting devices arranged with spaces; and etching the display panel having the light emitting layer to form a via, the via passing through the organic lighting devices and the insulating layer from a cathode layer of the organic lighting devices to a surface of the signal line layer.

Optionally, the manufacturing method further includes filling the via with a conductive material after the via is formed.

According to an embodiment of the present invention, a display device is provided. The display device comprises the above-mentioned display panel.

In contrast to the conventional art, an embodiment of the present invention positions the signal lines under the middle portion of the display area and utilizes a via to connect the cathode layer of the display area to the signal lines. Therefore, there is no need to put the signal lines in the side frame area such that the narrow side frame design is accomplished.

### BRIEF DESCRIPTION OF THE DRAWINGS

The accompanying drawings described herein are used to provide further comprehension of the present disclosure, and is a part of the present application. Schematic embodiments of the present disclosure and the description thereof are used to illustrate the present disclosure, but do not constitute any improper limit to the present disclosure. In the accompanying drawings:

FIG. 1 is a diagram of a display panel according to an embodiment of the present invention.

FIG. 2 is a diagram of a structure of a via according to an embodiment of the present invention.

FIG. 3 is a diagram of a display panel according to another embodiment of the present invention.

FIG. 4 is a flow chart of diagram of a manufacturing method of the display panel according to an embodiment of the present invention.

### DETAILED DESCRIPTION OF PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Specifically, the terminologies in the embodiments of the present invention are merely for describing the purpose of the certain embodiment, but not to limit the invention. Examples and the appended claims be implemented in the present invention requires the use of the singular form of the book “an”, “the” and “the” are intended to include most forms unless the context clearly dictates otherwise. It should also be understood that the terminology used herein that “and/or” means and includes any or all possible combinations of one or more of the associated listed items.

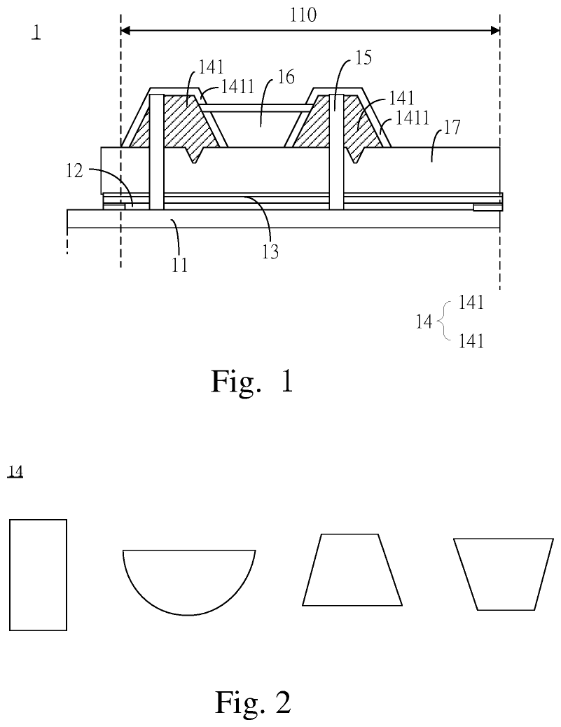

Please refer to FIG. 1. FIG. 1 is a diagram of a display panel according to an embodiment of the present invention. As shown in FIG. 1, the display panel 1 comprises: a substrate 11, a signal line layer 12, an insulating layer 13, a light emitting layer 14 and a via 15. The substrate comprises a display area 110. The signal line layer 12 is positioned above the substrate 11 and has an edge pasted on an edge of the display area 110. The insulating layer 13 covers the signal line layer 12 and has an edge pasted on an edge of the signal line layer 12. The light emitting layer 14 is positioned above the insulating layer 13. The light emitting layer 14 comprises a plurality of organic lighting devices 141 arranged with spaces between each other. The via 115 passes through the organic lighting devices 141 and the insulating layer 13 from a cathode layer 1411 of the organic lighting devices 141 to a surface of the signal line layer 12.

The substrate 11 could be organic solid, inorganic solid or a combination of organic solid and inorganic solid. The substrate could be rigid or flexible and could be processed to become individual parts (such as pieces or wafers) or continuous rolls. A typical substrate material comprises glass, plastic, metal, ceramics, semiconductor, metal oxide, metal nitride, metal sulfide, semiconductor oxide, semiconductor nitride, semiconductor sulfide, carbon, the combination thereof, or any other material that could be used to form OLED device in a passive matrix display or an active matrix display. The substrate 11 could be a mixture or a compound of materials or multi-layer materials. The substrate 11 could be an OLED substrate, which is a substrate normally used for OLED devices, such as active low temperature poly-silicon substrate or amorphous silicon TFT (thin film transistor) substrate.

Please refer to FIG. 2. FIG. 2 is a diagram of a structure of a via according to an embodiment of the present invention. The shape of the cross section of the via 15 comprises one of rectangular, half circle, and trapezoid. The maximum width of the via is less than or equal to 150 microns. Please note, when the via is a trapezoid or a reversed trapezoid, the maximum width of the via represents the dimension of the larger one of the trapezoid (it could be either the top or the bottom depending on which one is larger).

The organic lighting device 141 comprises a hole inject layer (HIL), a hole transport layer (HTL), an emitting material layer (EML), an electron transport layer (EHL), and an electron inject layer (EIL) (not shown) and these layers are stacked together. Further, the cathode layer 1411 is positioned above the electron inject layer.

The insulating layer 13 could be manufactured with the inorganic insulating material. The inorganic insulating material comprises one or a combination of silicon oxide (SiOx), silicon nitride (SiNx), silicon oxynitride (SiONx).

Furthermore, the material of the insulating layer 13 could comprise one or a combination of low temperature poly-silicon (LTPS) and silicon nitride (SiNx). For the LCD display, using LTPS allows the TFT circuit to be thinner, smaller, and lower power consuming.

Please refer to FIG. 1. The display panel 1 further comprises the matrix substrate 17. The matrix substrate is made by pixel units arranged in a matrix, which may comprises TFTs, storage capacitors and pixel electrodes (not shown). Please note, the opening of the matrix substrate, the pixel area 16 shown in FIG. 1, is used to display images in the display panel 1.

The via 15 is filled by a conductive material (not shown). The organic lighting devices 141 and the signal line layer 12 are electrically connected through the conductive material.

The conductive material comprises one or a combination of silver, copper, or LTPS.

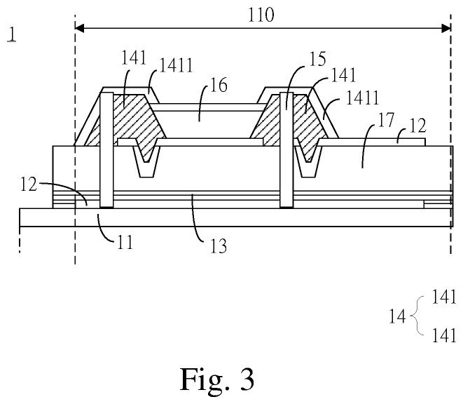

Please refer to FIG. 3. FIG. 3 is a diagram of a display panel according to another embodiment of the present invention. The matrix substrate 17 of the display panel further comprises a signal line layer 12. The edge of the signal line layer 12 is pasted on the edge of the display area 110. Further, in FIG. 3, the signal line layer 12 is positioned underneath the organic lighting device 141 through the punching such that the signal line layer 12 could be electrically connected to the organic lighting device 141 through the via and thus the signal line layer 141 is connected to the matrix substrate 17. In addition, in the display panel 1, the signal line layer 12 on the substrate 11 transfer the electric signal to the cathode layer 141 through the via 15 and then to the signal line layer 12 on the matrix substrate to form the circuit. At the same time, the display panel does not have the side frame area such that a narrow side frame design could be accomplished.

In an embodiment, the display panel 1 further comprises a packaging film layer (not shown) covering the light emitting layer 14. The edge of the packaging film is pasted on the edge of the display area 110.

The structure of the packaging film layer comprises stacked a polyvinyl alcohol (PVA) layer, a tri-cellulose acetate (TAC) layer, a PSA film, a release film, and a protective film.

The display panel is a flexible screen with a touch function and could further comprise a touch layer (not shown) positioned above the packaging film layer.

An embodiment of the present invention positions the signal lines under the middle portion of the display area and utilizes a via to connect the cathode layer of the display area to the signal lines. Therefore, there is no need to put the signal lines in the side frame area such that the narrow side frame design is accomplished.

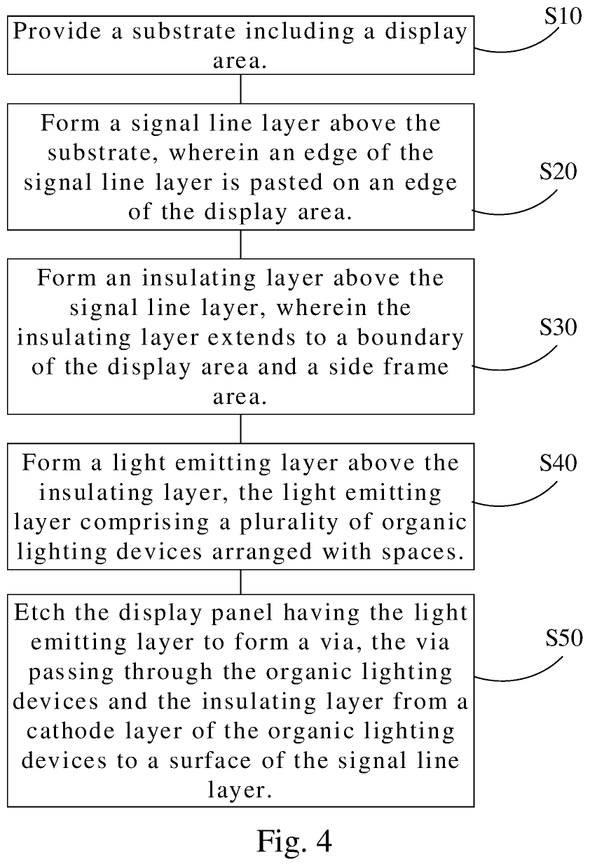

Please refer to FIG. 4. FIG. 4 is a flow chart of diagram of a manufacturing method of the display panel according to an embodiment of the present invention. The manufacturing method comprises:

S10: provide a substrate including a display area;

S20: form a signal line layer above the substrate, wherein an edge of the signal line layer is pasted on an edge of the display area;

S30: form an insulating layer above the signal line layer, wherein the insulating layer extends to a boundary of the display area and a side frame area;

S40: form a light emitting layer above the insulating layer, the light emitting layer comprising a plurality of organic lighting devices arranged with spaces;

S50: etch the display panel having the light emitting layer to form a via, the via passing through the organic lighting devices and the insulating layer from a cathode layer of the organic lighting devices to a surface of the signal line layer.

After the step S50, the method could further comprise: filling the via with a conductive material after the via is formed.

Please note, the above-mentioned the conductive material comprises one or a combination of silver, copper, or low temperature polysilicon.

In this embodiment, the above-mentioned display panel and its manufacturing method could be used in the development of OLED TFT technology, quantum dot light emitting diode (OLED) technology, or micro LED TFT technology.

Further, an electronic equipment is provided. The electronic equipment comprises the display panel in any of the above-mentioned embodiment, and it could be a cell phone, flat computer, a television, a display device, a laptop, a digital picture frame, a navigator, or any other products or device having a display function.

In this embodiment, the above-mentioned display panel and its manufacturing method could be used in the development of OLED TFT technology, quantum dot light emitting diode (OLED) technology, or micro LED TFT technology.

In addition to the display panel disclosed in the above-mentioned embodiments, the display device could be an LCD display or an e-ink display. An AMOLED has a super high response speed, wide color field, and high contrast and thus is considered a next generation display. Further, the AMOLED could be used on a flexible substrate such that the display device could be bendable and foldable. The flexible display device could have more functions and could be used in more applications.

Above are embodiments of the present invention, which does not limit the scope of the present invention. Any modifications, equivalent replacements or improvements within the spirit and principles of the embodiment described above should be covered by the protected scope of the invention.

What is claimed is:

1. A display panel, comprising:
a substrate, comprising a display area;
a signal line layer, positioned above the substrate, the signal line layer having an edge pasted on an edge of the display area;
an insulating layer, covering the signal line layer, the insulating layer having an edge pasted on an edge of the signal line layer;
a light emitting layer, positioned above the insulating layer, the light emitting layer comprising a plurality of organic lighting devices arranged with spaces; and
a via, pass through the organic lighting devices and the insulating layer from a cathode layer of the organic lighting devices to a surface of the signal line layer.

2. The display panel of claim 1, wherein a shape of a cross section of the via comprises a rectangular, a half circle, or a trapezoid and a maximum width of the via is less than or equal to 150 microns.

3. The display panel of claim 1, wherein each of the organic lighting devices comprises stacked a hole inject layer, a hole transport layer, an electroluminescent layer, an electron transport layer, and an electron inject layer; wherein the cathode layer is positioned above the electron injection layer.

4. The display panel of claim 1, wherein the insulating layer is manufactured with inorganic insulating material comprising one or a combination of silicon oxide, silicon nitride, and silicon oxynitride.

5. The display panel of claim 1, wherein the via is filled by a conductive material and the organic lighting devices are electrically connected to the signal line layer through the conductive material.

6. The display panel of claim 5, wherein the conductive material comprises one or a combination of silver, copper, or low temperature polysilicon.

7. The display panel of claim 1, wherein the display panel further comprises a packaging film layer covering the light emitting layer, and an edge of the packaging film layer is pasted on the edge of the display area.

8. A manufacturing method of a display panel, the manufacturing method comprising:
providing a substrate comprising a display area;
forming a signal line layer above the substrate, wherein an edge of the signal line layer is pasted on an edge of the display area;
forming an insulating layer above the signal line layer, wherein the insulating layer extends to a boundary of the display area and a side frame area;
forming a light emitting layer above the insulating layer, the light emitting layer comprising a plurality of organic lighting devices arranged with spaces; and
etching the display panel having the light emitting layer to form a via, the via passing through the organic lighting devices and the insulating layer from a cathode layer of the organic lighting devices to a surface of the signal line layer.

9. The manufacturing method of claim 8, further comprising:
filling the via with a conductive material after the via is formed.

10. A display device, comprising a display panel of claim 1.
